(19) United States
(12) Patent Application Publication
(10) Pub. No.: US 2005/0161782 A1
(43) Pub. Date: Jul. 28, 2005

(54) HYBRID INTEGRATED CIRCUIT DEVICE AND MANUFACTURING METHOD OF THE SAME

(75) Inventor: Masaru Kanakubo, Gunma (JP)

Correspondence Address: WATCHSTONE P + D, 1300 EYE STREET, NW, SUITE 400 EAST, WASHINGTON, DC, 20005, US

(73) Assignees: SANYO ELECTRIC CO., LTD., Osaka (JP); KANTO SANYO SEMICONDUCTORS CO., LTD., Gunma (JP)

(21) Appl. No.: 10/905,251

(22) Filed: Dec. 22, 2004

(30) Foreign Application Priority Data
Dec. 24, 2003 (JP) 2003-428410

(51) Int. Cl. H01L 23/02

(52) U.S. Cl. 257/678

(57) ABSTRACT

Provided are a hybrid integrated circuit device and a manufacturing method of the same, in which it is capable of molding while fixing a position of a board in a cavity. A method for manufacturing a hybrid integrated circuit device includes the steps of: forming an electric circuit which includes a conductive pattern formed on a surface of a circuit board, and a circuit element electrically connected to the conductive pattern; fixing a tip portion of a lead to a pad formed of the conductive pattern disposed along a side of the circuit board, the tip portion being fixed approximately perpendicularly to a surface direction of the circuit board; housing the circuit board in a cavity of molds, and allowing a rear surface of the circuit board to abut with a bottom of the cavity by clamping the lead between the molds; and performing sealing by filling inside of the cavity with a sealing resin to expose the rear surface of the circuit board to the outside.

### CROSS-REFERENCE TO RELATED APPLICATIONS

Priority is claimed to Japanese Patent Application Number JP2003-428410 filed on Dec. 24, 2003, the disclosure of which is incorporated herein by reference in its entirety.

1. Field of the Invention

The present invention relates to a hybrid integrated circuit device and a manufacturing method of the same. More particularly, the present invention relates to a hybrid integrated circuit device in which a rear surface of a circuit board is exposed out of a sealing resin, and a manufacturing method of the same.

2. Description of the Related Art

With reference to FIGS. 10A and 10B, a configuration of a conventional hybrid integrated circuit device will be described (for example, see Patent Document 1). FIG. 10A is a perspective view of a hybrid integrated circuit device 100, and FIG. 10B is a cross-sectional view taken along the line X-X′ in FIG. 10A.

With reference to FIGS. 10A and 10B, the conventional hybrid integrated circuit device 100 has the following configuration. The hybrid integrated circuit device 100 includes: a rectangular board 106; a conductive pattern 108 formed on an insulating layer 107 provided on a surface of the board 106; a circuit element 104 fixed on the conductive pattern 108; a metal wire 105 which electrically connects the circuit element 104 to the conductive pattern 108; and a lead 101 electrically connected to the conductive pattern 108. As described above, the entire hybrid integrated circuit device 100 is sealed with a sealing resin 102. As a method for sealing the device with the sealing resin 102, injection molding using thermoplastic resin and transfer molding using thermosetting resin can be used.

With reference to FIGS. 11A and 11B, description will be given of a step of performing resin sealing by the transfer molding. FIGS. 11A and 11B are cross-sectional views showing a state where the resin sealing is performed by use of molds 110.

With reference to FIG. 11A, on the surface of the board 106, an electric circuit including the circuit element 104 and the like is formed. This board 106 is fixed by upper and lower molds 110A and 110B. By engaging the upper and lower molds 110A and 110B, a cavity that is a space to be filled with resin is formed. By clamping a lead frame 101A between the upper and lower molds 110A and 110B, a position of the lead frame is fixed. Here, a shape of cross section of the lead frame 101A formed by punching or the like includes some differences. Accordingly, a certain amount of gap is formed between the lead frame 101A and the lower mold 110B.

With reference to FIG. 11B, by fitting the upper and lower molds 110A and 110B together, the lead frame 101A is fixed. Thereafter, the inside of the cavity is filled with resin. Thus, a molding step is performed with a rear surface of the board 106 exposed to the outside.

After sealing is performed in the above-described step, the hybrid integrated circuit device is completed as a product through an after cure step of stabilizing a property of the thermosetting resin, and the like.

[Patent Document 1] Japanese Patent Laid-Open No. Hei 6 (1994)-177295 (Page 4, FIG. 1).

### SUMMARY OF THE INVENTION

However, the method for manufacturing a hybrid integrated circuit device as described above has the following problems.

The lead frame 101A is fixed to the board 106 through a portion extending diagonally to a surface direction of the board 106. Therefore, when an external force which presses down the lead frame 101A acts on the lead frame by clamping the lead frame 101A between the molds 110A and 110B, downward and lateral external forces act on the board 106. Thus, as shown in FIG. 11B, the board 106 may be inclined in the cavity. If the sealing step is performed in this state, there is a problem of the position of the board 106 being unable to be fixed to a desired position. Moreover, since the resin sealing is performed with stress acting on the lead frame 101A, there is a problem of reliability of a connection portion between the lead frame 101A and the board 106 being lowered. Furthermore, there is also a problem of realization of a structure, in which the rear surface of the board 106 is exposed out of the sealing resin, being difficult.

The present invention was made in consideration for the foregoing problems. Therefore, a main aspect of the present invention is to provide a hybrid integrated circuit device and a manufacturing method of the same, in which it is capable of molding while fixing a position of a board in a cavity.

A hybrid integrated circuit device of the present invention includes: a circuit board; a conductive pattern formed on a surface of the circuit board; a circuit element electrically connected to the conductive pattern; and a lead fixed to a pad formed of the conductive pattern. A tip portion of the lead is fixed to the pad approximately perpendicularly to a surface direction of the circuit board.

A method for manufacturing a hybrid integrated circuit device of the present invention includes the steps of: forming an electric circuit which includes a conductive pattern formed on a surface of a circuit board, and a circuit element electrically connected to the conductive pattern; fixing a tip portion of a lead to a pad formed of the conductive pattern, the tip portion being fixed approximately perpendicularly to a surface direction of the circuit board; housing the circuit board in a cavity of molds, and allowing a rear surface of the circuit board to abut with a bottom of the cavity by clamping the lead between the molds; and performing sealing by filling inside of the cavity with a sealing resin to expose the rear surface of the circuit board to the outside.

Moreover, in the preferred embodiment of the present invention, the lead is formed of a first extending portion which extends approximately horizontally to the surface direction of the circuit board, and a second extending portion which is continuous with the first extending portion through a bent portion, and extends approximately perpendicularly to the surface direction of the circuit board, and that the first extending portion is clamped by the molds.

Furthermore, in the preferred embodiment of the present invention, a portion from the vicinity of the bent portion of the lead to the tip portion thereof is bent in a shape of an arc, and a tangential direction of the tip portion is approximately at right angles to the surface direction of the circuit board.

Furthermore, in the preferred embodiment of the present invention, an angle at which the tip portion of the lead abuts with the circuit board is within a range from 80 degrees to 100 degrees.

Furthermore, in the preferred embodiment of the present invention, the rear surface of the circuit board is pressed against the bottom of the cavity through the lead by clamping the lead between the molds.

The following effects can be achieved by the present invention.

According to the hybrid integrated circuit device of the present invention, the tip portion of the lead extends perpendicularly to the circuit board and is fixed to the pad. Therefore, the pad required to fix the lead can be made smaller, and the entire device can be miniaturized. Furthermore, a connection portion between the lead and the pad is covered with the sealing resin. Connection reliability of the lead is improved by the sealing resin.

According to the method for manufacturing a hybrid integrated circuit device of the present invention, by clamping the lead between the molds, the lead having its tip portion fixed approximately perpendicularly to the circuit board, the rear surface of the circuit board is allowed to abut with the bottom of the cavity in the molding step. Therefore, a lateral external force caused by fixing the lead does not act on the circuit board. Thus, in the molding step, it is possible to prevent the rear surface of the circuit board from coming off the bottom of the cavity.

### BRIEF DESCRIPTION OF THE DRAWINGS

FIG. 1A is a perspective view , FIG. 1B is a cross-sectional view, and FIG. 1C is a cross-sectional view showing a hybrid integrated circuit device of the preferred embodiment.

FIG. 2A is a plan view and FIG. 2B is a cross-sectional view showing a method for manufacturing a hybrid integrated circuit device of the preferred embodiment.

FIG. 3 is a plan view showing the method for manufacturing a hybrid integrated circuit device of the preferred embodiment.

FIG. 4A is a plan view and FIG. 4B is a cross-sectional view showing the method for manufacturing a hybrid integrated circuit device of the preferred embodiment.

FIGS. 5A to 5C are cross-sectional views showing the method for manufacturing a hybrid integrated circuit device of the preferred embodiment.

FIGS. 6A and 6B are cross-sectional views showing the method for manufacturing a hybrid integrated circuit device of the preferred embodiment.

FIG. 7 is a cross-sectional view showing the method for manufacturing a hybrid integrated circuit device of the preferred embodiment.

FIG. 8 is a plan view showing the method for manufacturing a hybrid integrated circuit device of the preferred embodiment.

FIG. 9 is a plan view showing the method for manufacturing a hybrid integrated circuit device of the preferred embodiment.

FIG. 10A is a perspective view and FIG. 10B is a cross-sectional view showing a conventional hybrid integrated circuit device.

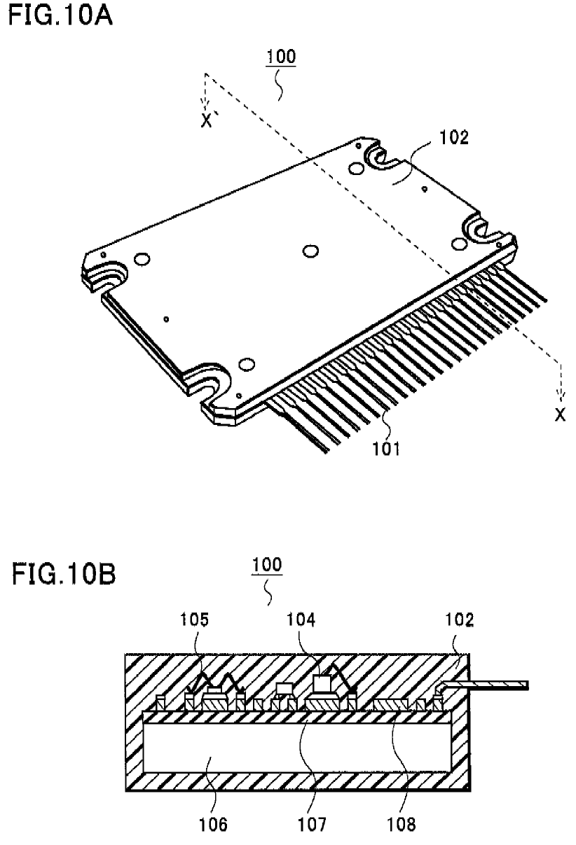

FIGS. 11A and 11B are cross-sectional views showing a method for manufacturing the conventional hybrid integrated circuit device.

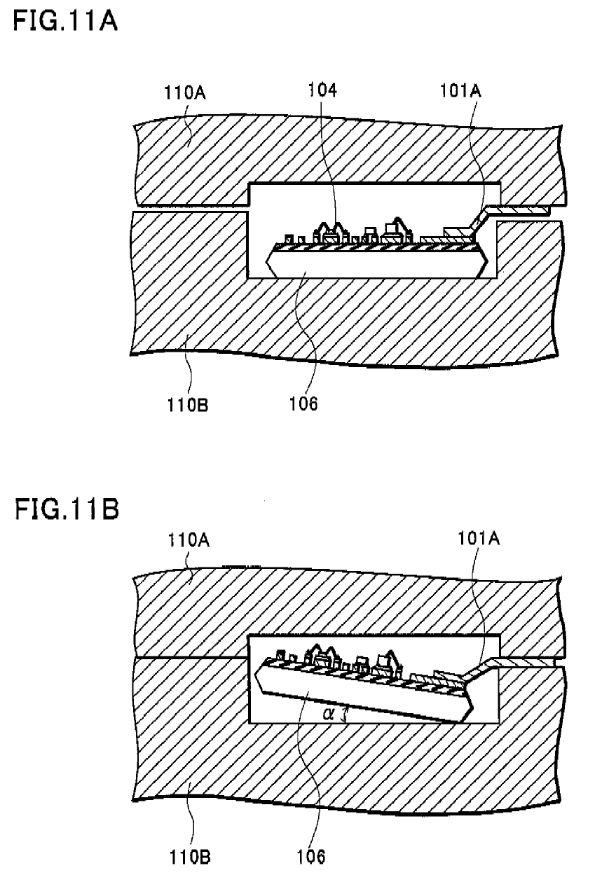

### DESCRIPTION OF THE EMBODIMENTS

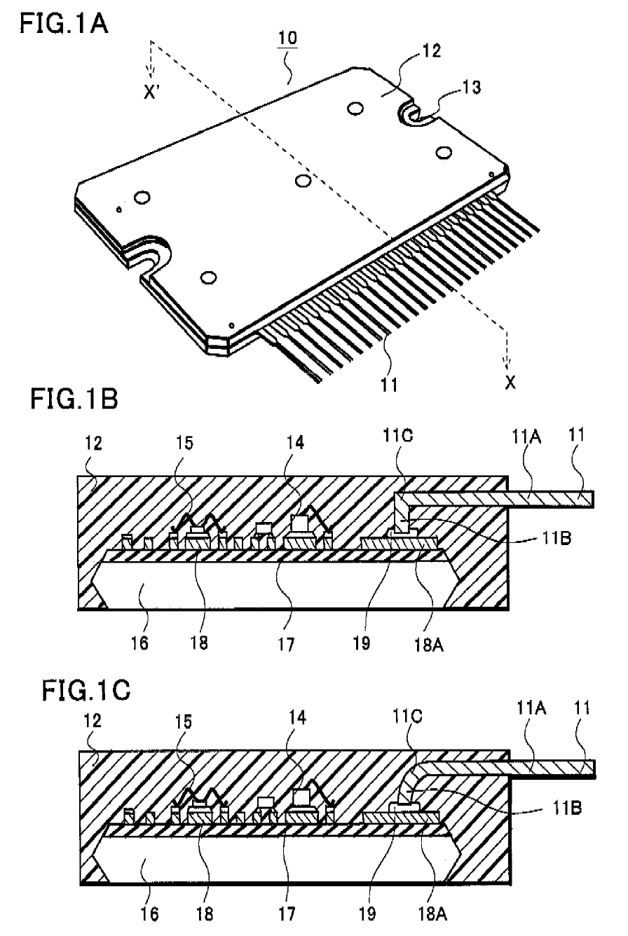

With reference to FIGS. 1A to 1C, a configuration of a hybrid integrated circuit device 10 according to an preferred embodiment of the present invention will be described. FIG. 1A is a perspective view of the hybrid integrated circuit device 10, and FIG. 1B is a cross-sectional view taken along the line X-X′ in FIG. 1A.

The hybrid integrated circuit device 10 of according to the preferred embodiment of the present invention includes: a circuit board 16 having an electric circuit formed on its surface, the electric circuit including a conductive pattern 18 and a circuit element 14; and a sealing resin 12 which seals the electric circuit and covers at least the surface of the circuit board 16. The respective constituent components as described above will be described below.

The circuit board 16 is a board made of metal such as aluminum and copper. When a board made of aluminum is employed as one example of the circuit board 16, there are two methods for insulating the circuit board 16 from the conductive pattern 18 formed on its surface. One is a method for anodizing a surface of an aluminum board. The other is a method for forming an insulating layer 17 on the surface of the aluminum board, and forming the conductive pattern 18 on a surface of the insulating layer 17. Here, in order to suitably release the heat to the outside, the heat being generated from the circuit element 14 mounted on the surface of the circuit board 16, a rear surface of the circuit board 16 is exposed to the outside from the sealing resin 12.

The circuit element 14 is fixed onto the conductive pattern 18, and the circuit element 14 and the conductive pattern 18 form a predetermined electric circuit. As the circuit element 14, an active element such as a transistor and a diode, or a passive element such as a capacitor and a resistor is adopted. Moreover, an element with a large heat dissipation amount such as a power system semiconductor element may be fixed to the circuit board 16 with a heatsink made of metal interposed therebetween. Here, the active element which is mounted face up, or the like is electrically connected to the conductive pattern 18 through a metal wire 15.

The conductive pattern 18 is made of metal such as copper, and is formed so as to be insulated from the circuit board 16. Moreover, on a side from which the lead 11 is led, a pad 18A formed of the conductive pattern 18 is formed. Here, in the vicinity of one of the sides of the circuit board 16, a plurality of pads 18A are arranged in line. Furthermore, the conductive pattern 18 is bonded to the surface of the circuit board 16 by use of the insulating layer 17 as an adhesive.

The pad 18A is formed of a part of the conductive pattern 18, and is a part to which the lead 11 is fixed. In this embodiment, a tip portion of a second extending portion 11B, which extends approximately perpendicularly to the circuit board 16, abuts with the pad 18A. Therefore, a size of the pad 18A may be slightly larger than that of a cross section of the lead 11. Thus, the respective pads 18A can be made smaller, and the entire device can be miniaturized.

The lead 11 is fixed to the pad 18A provided in a peripheral portion of the circuit board 16. The lead 11 has a function of, for example, performing input/output between the device and the outside. Here, a number of leads 11 are provided on one side. The lead 11 is bonded to the pad 18A by use of a conductive adhesive such as solder (a brazing material). Moreover, it is also possible to provide the pad 18A on opposite sides of the circuit board 16 and to fix leads 11 to these pads.

With reference to FIG. 1B, the lead 11 is formed of first and second extending portions 11A and 11B which are continuous with each other through a bent portion 11C. The first extending portion 11A extends approximately horizontally to a surface direction of the circuit board 16. The second extending portion 11B extends approximately perpendicularly to the surface direction of the circuit board 16, and the tip portion thereof is fixed to the pad 18A by use of a brazing material 19. In this embodiment, it is preferable that the second extending portion 11B abuts with the pad perpendicularly to the surface direction of the circuit board 16. However, an angle formed by the second extending portion 11B and the surface direction of the circuit board 16 may be between 80 degrees and 100 degrees.

With reference to FIG. 1C, here, the lead 11 is bent in a shape of an arc. Specifically, the first extending portion 11A extends approximately parallel to the surface direction of the circuit board 16. The tip portion of the second extending portion 11B extending in an arc through the bent portion 11C is fixed to the pad 18A with the brazing material 19 interposed therebetween.

The sealing resin 12 is formed by transfer molding using thermosetting resin or by injection molding using thermoplastic resin. Here, the sealing resin 12 is formed so as to seal the circuit board 16 and the electric circuit formed on the surface thereof, and the rear surface of the circuit board 16 is exposed out of the sealing resin 12.

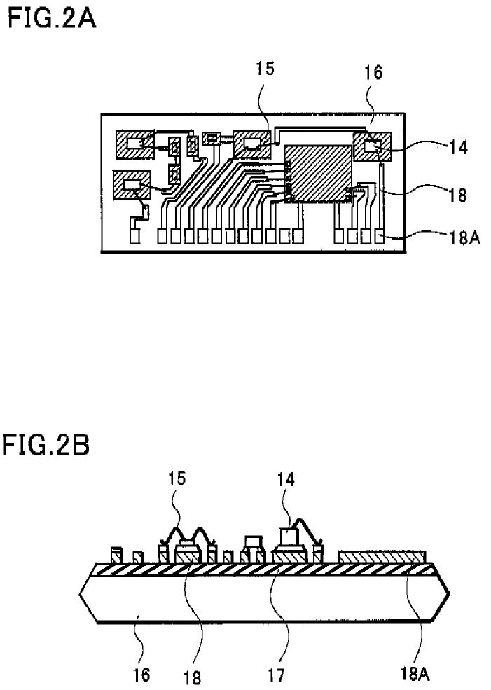

With reference to FIGS. 2A to 9, a method for manufacturing a hybrid integrated circuit device 10 will be described. The method for manufacturing a hybrid integrated circuit device 10 includes the steps of: forming the electric circuit which includes a conductive pattern 18 formed on a surface of a circuit board 16, and a circuit element 14 electrically connected to the conductive pattern 18; fixing a tip portion of a lead 11 to a pad 18A formed of the conductive pattern 18 disposed along a side of the circuit board, the tip portion being fixed approximately perpendicularly to the surface direction of the circuit board 16; housing the circuit board 16 in a cavity 31 of molds 30, and allowing the rear surface of the circuit board 16 to abut with a bottom of the cavity 31 by clamping the lead 11 between the molds 30; and performing sealing by filling inside of the cavity 31 with a sealing resin 12 to expose the rear surface of the circuit board 16 to the outside. This manufacturing method will be described below.

First, with reference to FIGS. 2A and 2B, the electric circuit including the conductive pattern 18 and the circuit element 14 is formed on the surface of the circuit board 16. As a method for forming the conductive pattern 18, first, a conductive foil is bonded to the surface of the circuit board 16 with an insulating layer 17 interposed therebetween. Thereafter, by etching this conductive foil, the conductive pattern 18 having a desired pattern shape is obtained. Furthermore, the circuit element 14 is disposed in a desired spot of the conductive pattern 18, and is electrically connected to the conductive pattern 18 by use of the thin metal wire 15. Thus, a desired electric circuit is formed. As the circuit element 14, an active element such as a semiconductor element, or a passive element such as a resistor and a capacitor can be generally adopted. Moreover, an element with a large heat dissipation such as a power system semiconductor element may be fixed to the circuit board 16 with a heatsink or the like interposed therebetween.

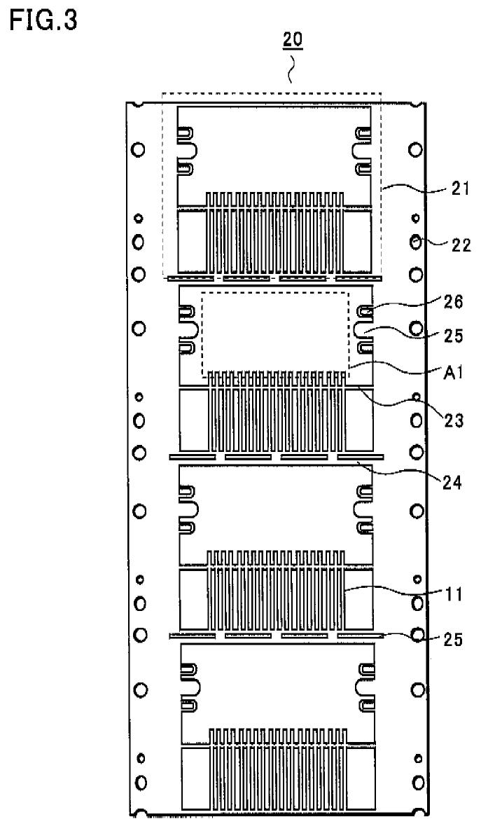

Next, with reference to FIGS. 3 to 5C, a step of fixing the lead 11 to the circuit board 16 will be described. First, with reference to FIG. 3, a structure of a lead frame 20 will be described. In the preferred embodiment of the present invention, the lead 11 is provided in a state of the lead frame 20. Specifically, in the lead frame 20 of this embodiment, a plurality of units 21 are formed. Each of the units 21 includes leads 11 and a region A1 in which the circuit board 16 is disposed. Furthermore, the lead frame 20 has a rectangular shape, and the plurality of units 21 are arranged with the respective units 21 being separated from each other at predetermined intervals. Between the respective units 21, slits 25 are provided, which absorb thermal stress generated in a step accompanied by heating such as a molding step. Moreover, in both peripheral portions in a longitudinal direction of the lead frame 20, guide holes 22 are provided, which are used for positioning in each step. Furthermore, the plurality of leads 11 provided in each unit 21 are connected by first and second connection portions 23 and 24, and the shape and position thereof are fixed.

In each unit 21, a supporting portion 26 and a protrusion portion 25 are provided. The protrusion portion 25 is a portion extending inward from both edges of each unit 21, and its planar shape and position are formed to be the same as those of a fixing portion 13 shown in FIG. 1A. The supporting portion 26 is embedded in the sealing resin in a resin sealing step to be performed later. Thus, the supporting portion 26 has a function of integrally connecting the circuit device and the lead frame 20 until the final step. The supporting portion 26 has a shape having a hole therein. By filling this hole with the sealing resin, a bonding strength between the supporting portion 26 and the sealing resin is improved. Moreover, the supporting portions 26 are formed on opposed sides of each unit 21, two on each side. Accordingly, in a subsequent step, bonding between the circuit device and the lead frame 20 is enhanced. Furthermore, by providing the hole in the supporting portion 26 as described above, mechanical bonding between the supporting portion 26 and the lead frame 20 is weakened. Thus, division of the circuit device and the lead frame 20 in a subsequent step can be facilitated. Moreover, the supporting portions 26 are formed in a region of the unit 21, the region excluding the region A1 in which the circuit board 16 is to be disposed. By disposing the supporting portions 26 as described above, it is possible to prevent lowering of moisture resistance of the circuit device due to embedding of the supporting portions 26 in the sealing resin.

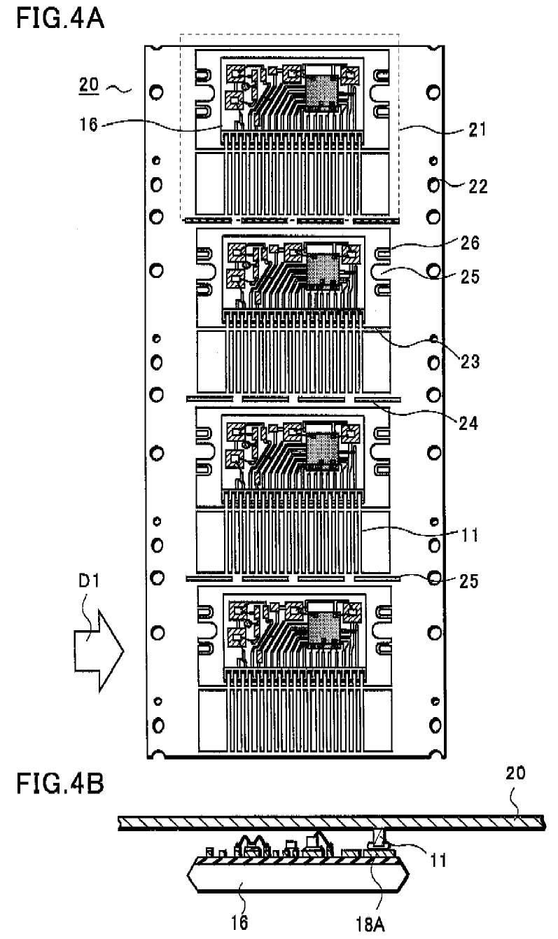

Next, with reference to FIGS. 4A and 4B, the circuit board 16 is fixed to each of the units 21 of the lead frame 20. FIG. 4A is a plan view showing this step, and FIG. 4B is a cross-sectional view from a cross-section direction D1. The fixing of the circuit board 16 to the lead frame 20 is performed by fixing the tip portion of the lead 11 in each unit 21 to the pad 18A of the circuit board 16 by use of a brazing material such as solder. With reference to FIG. 4B, a part of the lead 11, which is fixed to the pad 18A, abuts with the circuit board 16 in a direction approximately perpendicular to the circuit board 16.

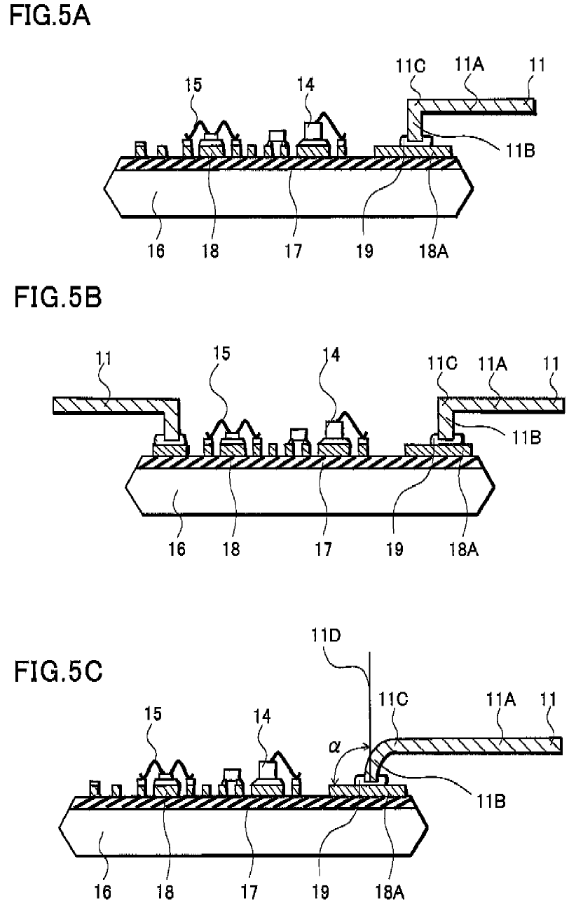

Next, with reference to FIGS. 5A to 5C, related configurations of the lead 11 and the circuit board 16 will be described. FIGS. 5A to 5C are cross-sectional views showing connection structures of the lead 11 in the respective configurations.

With reference to FIG. 5A, here, the lead 11 is fixed to the pad 18A provided on one side. Specifically, the tip portion of the second extending portion 11B extending perpendicularly to the surface direction of the circuit board 16 is fixed to the pad 18A by use of the brazing material.

With reference to FIG. 5B, here, the pads 18A are provided on two sides facing each other, and the leads 11 are fixed to those pads 18A. Although, here, the leads 11 are fixed to the two sides, the leads 11 can also be fixed to four sides.

With reference to FIG. 5C, here, the tip portion of the second extending portion 11B extending in a shape of an arc is fixed to the pad 18A. Here, the tip portion of the second extending portion 11B formed to have the arc shape abuts with the circuit board 16 approximately perpendicularly to the surface direction thereof. Specifically, a tangential direction 11D of the tip portion of the second extending portion 11B is set to be at right angles to the surface direction of the circuit board 16. Moreover, in this embodiment, an angle α formed by the tangential direction 11D and the surface direction of the circuit board 16 can be changed within a range from 80 degrees to 100 degrees. If the angle is α within this range, it is possible to prevent the rear surface of the circuit board 16 from coming off the bottom of the cavity 31 in the subsequent molding step.

If the foregoing angle α is less than 80 degrees or larger than 100 degrees, in the subsequent molding step, when a downward external force acts on the first extending portion 11A of the lead 11, the lead 11 may be deformed at the bent portion 11C. If the lead 11 is deformed, there arises such a problem of the circuit board 16 being moved laterally, or the circuit board 16 being inclined.

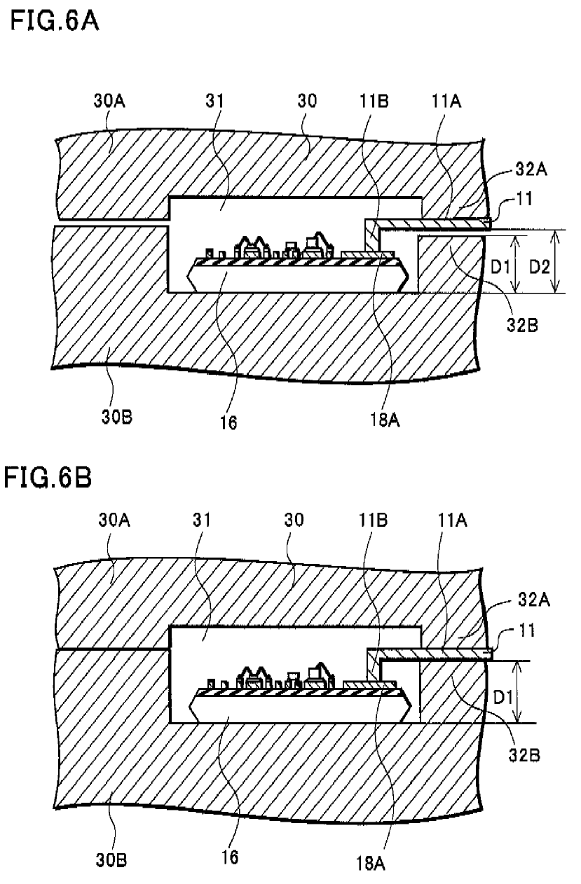

Next, with reference to FIGS. 6A to 8, the rear surface of the circuit board 16 is exposed, and sealing is performed by use of the sealing resin 12. First, with reference to FIGS. 6A and 6B, the circuit board 16 is housed in the inside of the molds 30 to perform sealing. FIGS. 6A and 6B are cross-sectional views of this step. Here, description will be given of a method for sealing one circuit board 16. However, in reality, this step is performed in a state where a plurality of circuit boards 16 are connected by the lead frame 20.

First, with reference to FIG. 6A, description will be given of a related configuration of the molds 30 to perform sealing, and the circuit board 16. The molds 30 include upper and lower molds 30A and 30B. The cavity 31 that is a space for sealing is formed by allowing the both molds to abut with each other from above and below. Furthermore, in the upper and lower molds 30A and 30B, contact portions 32A and 32B are provided. These contact portions 32 clamp the lead 11, and a planar position of the circuit board 16 is fixed. FIG. 6A shows a state where the circuit board 16 is mounted on the lower mold 30B, and thereafter, the upper mold 30A is made to abut with the lower mold 30B. Here, a distance in a vertical direction between the bottom of the cavity 31 and an upper end of the contact portion 32B of the lower mold is set to D1. In addition, a distance in the vertical direction between a lower surface of the circuit board 16 and a lower surface of the lead 11 is set to D2. In this embodiment, D1 is set to be shorter than D2. According to this configuration, when the circuit board 16 is mounted in the bottom of the lower mold 30B, a gap corresponding to a difference between D1 and D2 is formed between the lead 11 and the contact portion 32B.

With reference to FIG. 6B, the upper mold 30A is pressed down until the lead 11 comes into contact with the contact portion 32B. Thus, in the cavity 31, the circuit board 16 is pressed against the bottom of the cavity 31. Specifically, the contact portion 32A presses down the first extending portion 11A of the lead 11, and thus the circuit board 16 is indirectly pressed down. Moreover, since the second extending portion 11B of the lead 11 extends perpendicularly to the circuit board 16, a lateral external force due to the foregoing pressing is hardly generated. Therefore, in this step, it is possible to prevent coming off of the circuit board 16 due to pressing of the lead 11. Furthermore, since the circuit board 16 and the bottom of the cavity can be allowed to come into close contact with each other, it is also possible to prevent the sealing resin from running around the rear surface of the circuit board 16.

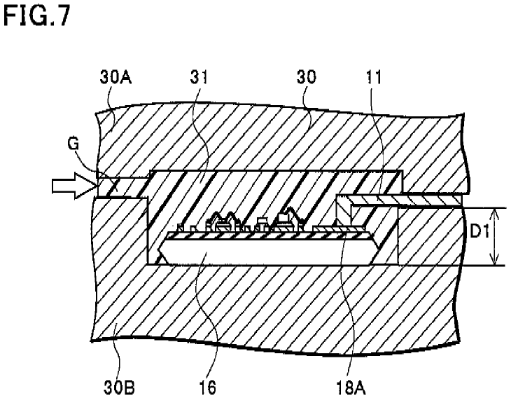

With reference to FIG. 7, by filling the cavity 31 with the sealing resin 12 through a gate G, molding is performed. The gate G is provided in a spot of a side of the mold 30, the spot being positioned above the upper surface of the circuit board 16. In FIG. 7, the gate G is provided in the side opposite to the side to which the lead 11 is fixed. However, the gate G may be provided in a side of a mold positioned in a depth direction in the plane of paper. The sealing is performed until the cavity 31 is filled with the sealing resin 12. Thus, the molding step is finished. In the sealing step, the rear surface of the circuit board 16 abuts with the bottom of the cavity. Thus, the rear surface of the circuit board 16 is exposed out of the sealing resin 12.

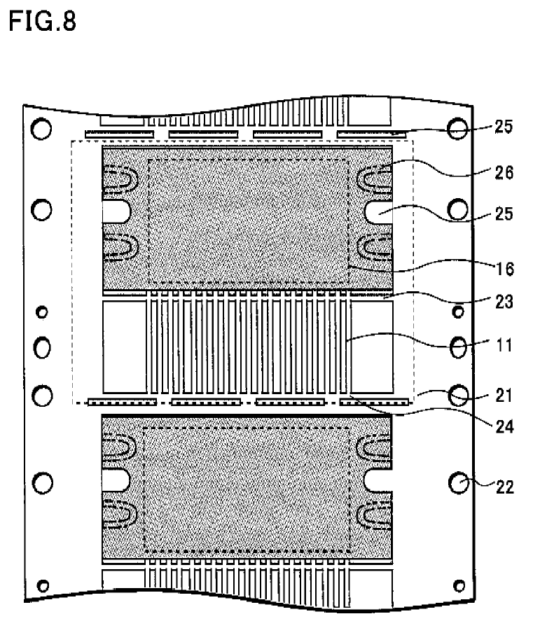

With reference to FIG. 8, description will be given of a planar state of the lead frame 20 after the molding step is finished. FIG. 8 is a plan view showing an enlarged part of the lead frame 20 shown in FIG. 3.

The sealing resin is formed so as to seal the circuit board 16 fixed to each unit 21. The sealing resin 12 is not formed in a spot corresponding to a region of the protrusion portion 25. Therefore, this spot becomes the fixing portion 13 as shown in FIG. 1A. Moreover, the supporting portion 26 has been embedded in the sealing resin 12 in the molding step. In FIG. 8, the supporting portion 26 embedded in the sealing resin is indicated by a dotted line.

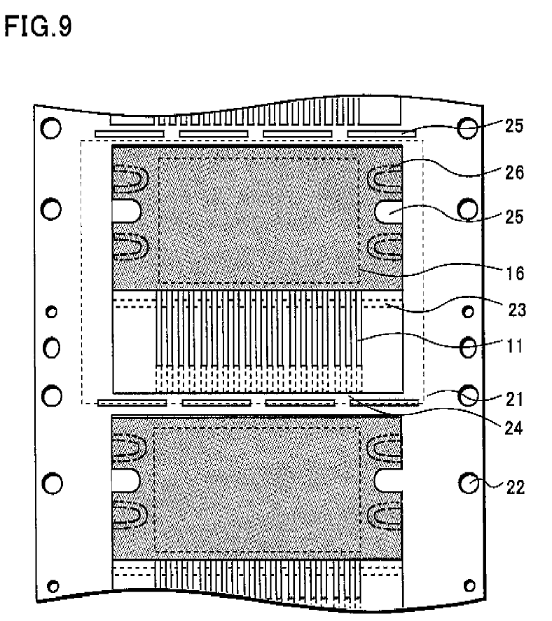

Next, with reference to FIG. 9, the leads 11 are separated from each unit 21. Here, the first connection portion 23 indicated by a dotted line is removed by a removal method such as punching, and the respective leads 11 are mechanically and electrically separated. Furthermore, portions of the leads 11, which are continuous with the second connection portion 24, are cut off to separate the leads 11 from the lead frame 20. By mechanically separating the leads 11 from the lead frame 20, the resin-sealed circuit board 16 and the lead frame 20 are connected to each other through the supporting portion 26. Therefore, in this embodiment, even after the leads 11 are separated, the hybrid integrated circuit device in each unit 21 and the lead frame 20 are integrally supported. Thus, this embodiment has an advantage that transport between the steps and the like can be easily performed.

After the above-described step is finished, the hybrid integrated circuit device 10 as shown in FIG. 1A, for example, is completed through a step of performing lead forming by bending the lead 11 in a desired shape, a step of separating each hybrid integrated circuit device from the lead frame 20, and a step of measuring electrical characteristics of each hybrid integrated circuit device.

1. A hybrid integrated circuit device comprising:
a circuit board;
a conductive pattern formed on a surface of the circuit board;
a circuit element electrically connected to the conductive pattern;
a lead fixed to a pad formed of the conductive pattern,
wherein a tip portion of the lead is fixed to the pad approximately perpendicularly to a surface direction of the circuit board.

2. The hybrid integrated circuit device according to claim 1, further comprising:
a sealing resin formed so as to cover at least a surface of the circuit element,
wherein a connection portion between the pad and the lead is covered with the sealing resin.

3. The hybrid integrated circuit device according to claim 1, wherein
the lead is formed of a first extending portion which extends approximately horizontally to the surface direction of the circuit board, and a second extending portion which is continuous with the first extending portion through a bent portion, and extends approximately perpendicularly to the surface direction of the circuit board, and
a tip of the second extending portion is fixed to the pad.

4. A method for manufacturing a hybrid integrated circuit device, comprising:
forming an electric circuit which includes a conductive pattern formed on a surface of a circuit board, and a circuit element electrically connected to the conductive pattern;
fixing a tip portion of a lead to a pad formed of the conductive pattern, the tip portion being fixed approximately perpendicularly to a surface direction of the circuit board;
housing the circuit board in a cavity of molds, and allowing a rear surface of the circuit board to abut with a bottom of the cavity by clamping the lead between the molds; and
performing sealing by filling inside of the cavity with a sealing resin to expose the rear surface of the circuit board to the outside.

5. The method for manufacturing a hybrid integrated circuit device according to claim 4, wherein
the lead is formed of a first extending portion which extends approximately horizontally to the surface direction of the circuit board, and a second extending portion which is continuous with the first extending portion through a bent portion, and extends approximately perpendicularly to the surface direction of the circuit board, and the first extending portion is clamped by the molds.

6. The method for manufacturing a hybrid integrated circuit device according to claim 5, wherein
a portion from the vicinity of the bent portion of the lead to its tip portion is bent in a shape of an arc, and
a tangential direction of the tip portion is approximately at right angles to the surface direction of the circuit board.

7. The method for manufacturing a hybrid integrated circuit device according to claim 4, wherein
an angle at which the tip portion of the lead abuts with the circuit board is within a range from 80 degrees to 100 degrees.

8. The method for manufacturing a hybrid integrated circuit device according to claim 4, wherein
the rear surface of the circuit board is pressed against the bottom of the cavity through the lead by clamping the lead between the molds.
